(19) United States
(12) Patent Application Publication
(10) Pub. No.: US 2011/0147871 A1
(43) Pub. Date: Jun. 23, 2011

(54) SEMICONDUCTOR DEVICE AND METHOD OF MANUFACTURING THE SAME

(75) Inventors: Masaki UTSUMI, Kyoto (JP); Takahiro NAKANO, Kyoto (JP); Hikari SANO, Hyogo (JP)

(73) Assignee: PANASONIC CORPORATION, Osaka (JP)

(21) Appl. No.: 13/036,232

(22) Filed: Feb. 28, 2011

Related U.S. Application Data
(63) Continuation of application No. PCT/JP2010/000064, filed on Jan. 7, 2010.

(30) Foreign Application Priority Data
Jan. 19, 2009 (JP) 2009-009312

(51) Int. Cl. H01L 31/0232; H01L 31/18

(52) U.S. Cl. 257/432; 438/69; 257/E31.127

(57) ABSTRACT

To provide a semiconductor device and a method of manufacturing the same, which have a device structure ensuring high degrees of reliability and mass-productivity at low cost.

A semiconductor device includes: a substrate including an imaging area and having a first main surface and a second main surface; an electrode formed on the first main surface; an external electrode formed on the second main surface; a conductive portion which is formed in a through hole penetrating the substrate, and electrically connects the electrode and the external electrode; an optical element which is placed on the first main surface and has a convex surface including a convex portion; and a light transmitting element which is bonded to the optical element so as to cover the convex portion and has a flat upper surface.

### CROSS REFERENCE TO RELATED APPLICATION

This is a continuation application of PCT application No. PCT/JP2010/000064 filed on Jan. 7, 2010, designating the United States of America.

### BACKGROUND OF THE INVENTION

(1) Field of the Invention

The present invention relates to a semiconductor device including a semiconductor element, and to a method of manufacturing the semiconductor device. The semiconductor element is used for a digital camera, a cellular phone, and the like, and is, for example, a light receiving element such as an imaging device or a photo integrated circuit (IC).

(2) Description of the Related Art

In recent years, as the demand for the reduction in size, thickness, and weight of electronic devices grows, there is an increasing demand for high-density packaging of semiconductor devices. Moreover, combined with a high degree of integration of semiconductor devices achieved through the advances in microfabrication technology, a so-called “chip mounting technique” enabling direct mounting of a chip-size-package or bare-chip semiconductor element has been proposed.

For example, Japanese Unexamined Patent Application Publication No. 2007-12995 (referred to as Patent Reference 1 hereafter) discloses a device structure and a method of manufacturing a semiconductor imaging device, which achieve the reduction in thickness and cost of the semiconductor imaging device by bonding a transparent plate via an adhesive on an imaging area of a semiconductor element included in the semiconductor imaging device.

FIG. 6 is a cross-sectional diagram showing a structure of a semiconductor device 400 disclosed in Patent Reference 1. In the semiconductor device 400 shown in this diagram, a semiconductor chip 402 and a lens sheet 403 are formed on a substrate 401. It should be noted that the semiconductor chip 402 is placed between the substrate 401 and the lens sheet 403 via epoxy resin layers 404 and 405, respectively.

The substrate 401 has a trench 406 penetrating from a lower surface to an upper surface of the substrate 401, and also has a plurality of ball bumps 407. On the lower surface of the substrate 401, a conductive pattern 409 which electrically connects a connection terminal 408 and the ball bump 407 is formed.

The semiconductor chip 402, which is provided on the substrate 401 via the epoxy resin layer 404, has the connection terminal 408 placed so as to be exposed at the trench 406. The semiconductor chip 402 also includes an imaging device which is not illustrated in the drawing. The lens sheet 403, which is provided on the semiconductor chip 402 via the epoxy resin layer 405, has an imaging lens portion 410 which is convex in shape.

With this structure, the miniaturization of the semiconductor device 400 is achieved.

### SUMMARY OF THE INVENTION

However, the conventional semiconductor device as described above causes faulty mounting due to, for example, a suction error occurring when the semiconductor device is to be mounted on an electronic substrate. Thus, the above-described conventional technology has a problem that manufacturing yield is reduced, meaning that the cost is high while the reliability and mass-productivity are low.

For example, as shown in FIG. 6, the semiconductor device 400 disclosed in Patent Reference 1 includes the lens sheet 403 having the convex-shaped imaging lens portion 410 that is convex in the direction of thickness of the semiconductor device 400. Here, this convex shape of the lens sheet 403 is a factor responsible for faulty mounting caused by a suction error or the like occurring when the semiconductor device 400 is to be mounted on an electronic substrate.

Moreover, when the processing such as polishing is performed on the surface, on which the ball bump 407 is to be formed, for the purpose of thinning the semiconductor device 400, it is difficult to hold the semiconductor device 400 by suction because of the convex shape of the lens sheet 403. For this reason, the reduction in thickness of the semiconductor device 400 can be no longer achieved.

The present invention is conceived in view of the aforementioned problem, and has an object to provide a semiconductor device and a method of manufacturing the same, which prevent both a decrease in manufacturing yield and an increase in product cost and which ensure high degrees of reliability and mass-productivity.

In order to achieve the aforementioned object, the semiconductor device according to an aspect of the present invention is a semiconductor device including: a semiconductor element which includes an imaging area for converting light into an electric signal, and has a first main surface and a second main surface that is opposite to the first main surface; a first electrode formed on the first main surface; a second electrode formed on the second main surface; a conductive portion which is formed in a through hole penetrating the semiconductor element, and electrically connects the first and second electrodes so as to transmit, from the first electrode to the second electrode, the electric signal received from the imaging area; an optical element which is bonded to the first main surface via a bonding element so as to be positioned higher than the first main surface, has a convex surface including a convex portion, and refracts the light using the convex portion; and a light transmitting element which is bonded to the optical element so as to cover the convex portion, wherein one of the optical element and the light transmitting element that is positioned higher than the other has a flat upper surface.

With this, since one of the optical element and the light transmitting element that is positioned higher than the other has the flat upper surface, the semiconductor device can be easily held by suction when it is necessary, such as when component mounting is performed. Thus, the semiconductor device according to the present invention can be easily manufactured. Hence, a decrease in manufacturing yield and an increase in product cost can be both prevented. Also, the optical element having the convex portion allows the outside light to be efficiently collected on the imaging area. Accordingly, the miniaturization of the semiconductor device can be achieved.

Also, the convex portion may be convex upward, and the light transmitting element may be positioned higher than the optical element and may have a flat surface opposite to a surface to which the optical element is bonded.

With this, since the light transmitting element having the flat surface is bonded to the optical element having the convex portion, it is easy to hold the semiconductor device by suction when the semiconductor device is to be mounted on an electronic substrate. Accordingly, the manufacturing cost can be reduced. Moreover, when the processing such as polishing is performed on the second main surface of the semiconductor device, the semiconductor device can be held by suction at the flat surface of the light transmitting element. Hence, it becomes easy to thin the semiconductor device.

Moreover, the convex portion may be convex downward, and the optical element may be positioned higher than the light transmitting element and may have a flat surface opposite to the convex surface.

With this, since the optical element has the flat surface opposite to the convex surface, it becomes easy to hold the semiconductor device by suction when the semiconductor device is to be mounted on an electronic substrate.

Furthermore, a refractive index of the light transmitting element may be higher than a refractive index of air and lower than a refractive index of the optical element.

With this, since the refractive index of the light transmitting element is higher than that of air and lower than that of the optical element, outside light can almost vertically pass through an outside-light incident surface of the light transmitting element. As a result, the outside light can be reliably collected by the optical element having the convex portion. This can improve the quality of the semiconductor device.

Also, the convex portion may be formed in such a shape and at such a position that the light is directed toward the imaging area.

With this, the optical element having the convex portion allows the outside light to be efficiently collected on the imaging area. Accordingly, the miniaturization of the semiconductor device can be achieved.

Moreover, the light transmitting element may be made of an acrylic resin, and the optical element may be made of glass.

Furthermore, the semiconductor device according to another aspect of the present invention may be a semiconductor device including: a semiconductor element which includes an imaging area for converting light into an electric signal, and has a first main surface and a second main surface that is opposite to the first main surface; a first electrode formed on the first main surface; a second electrode formed on the second main surface; a conductive portion which is formed in a through hole penetrating the semiconductor element, and electrically connects the first and second electrodes so as to transmit, from the first electrode to the second electrode, the electric signal received from the imaging area; and an optical element which is positioned higher than the first main surface, and has: a convex surface including a convex portion that is convex downward; and a flat surface opposite to the convex surface.

With this, since the upper surface of the optical element is flat, it is easy to hold the optical element by suction. Thus, the manufacturing cost can be reduced, and the semiconductor device can be easily thinned.

The method of manufacturing the semiconductor device according to another aspect of the present invention is a semiconductor-device manufacturing method including: forming a semiconductor element which includes an imaging area for converting light into an electric signal and has a first main surface and a second main surface that is opposite to the first main surface; forming a first electrode on the first main surface; forming a through hole which penetrates the semiconductor element and forming, in the through hole, a conductive portion which is electrically connected to the first electrode; placing an optical element so as to be higher than the first main surface, the optical element having a convex surface including a convex portion; bonding a light transmitting element to the optical element so as to cover the convex portion; and forming, on the second main surface, a second electrode which is electrically connected to the conductive portion, wherein one of the optical element and the light transmitting element that is positioned higher than the other has a flat upper surface.

With this, since one of the optical element and the light transmitting element that is positioned higher than the other has the flat upper surface, the semiconductor device can be easily held by suction when it is necessary, such as when component mounting is performed. This means that the semiconductor device can be easily manufactured. Hence, it becomes possible to manufacture the semiconductor device which prevents both a decrease in manufacturing yield and an increase in product cost and which ensures high degrees of reliability and mass-productivity. Also, the optical element having the convex portion allows the outside light to be efficiently collected on the imaging area. Accordingly, the miniaturization of the semiconductor device can be achieved.

Also, the semiconductor-device manufacturing method may further includes polishing a surface opposite to the first main surface of the semiconductor element so as to form the second main surface, wherein, in the forming of a second electrode, the second electrode is formed on the second main surface obtained as a result of the polishing.

With this, the semiconductor device can be thinned through the polishing performed on the lower surface. Also, in this case, since the light transmitting element having the flat surface is bonded to the optical element having the convex portion, it is easy to perform the polishing by holding the flat surface of the light transmitting element by suction. Hence, the semiconductor device can be easily thinned.

The present invention can implement the semiconductor device which is reduced in size and thickness, which has an excellent optical property, and which ensures high degrees of reliability and mass-productivity. With this, manufacturing yield can be prevented from decreasing, and the manufacturing cost can also be accordingly reduced.

Further Information about Technical Background to This Application

The disclosure of Japanese Patent Application No. 2009-009312 filed on Jan. 19, 2009 including specification, drawings and claims is incorporated herein by reference in its entirety.

The disclosure of PCT application No. PCT/JP2010/000064 filed on, Jan. 7, 2010, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a detailed cross-sectional diagram showing a semiconductor device in a first embodiment.

FIG. 1B is a cross-sectional diagram explaining an optical property of the semiconductor device in the first embodiment.

FIG. 2 is a cross-sectional diagram showing each stage of a method of manufacturing the semiconductor device in the first embodiment.

FIG. 3A is a detailed cross-sectional diagram showing a semiconductor device in a second embodiment.

FIG. 3B is a cross-sectional diagram explaining an optical property of the semiconductor device in the second embodiment.

FIG. 4 is a cross-sectional diagram showing each stage of a method of manufacturing the semiconductor device in the second embodiment.

FIG. 5A is a detailed cross-sectional diagram showing a semiconductor device in a third embodiment.

FIG. 5B is a cross-sectional diagram explaining an optical property of the semiconductor device in the third embodiment.

FIG. 6 is a cross-sectional diagram showing a structure of a conventional semiconductor device.

### DESCRIPTION OF THE PREFERRED EMBODIMENTS

The following is a description of the semiconductor device and method of manufacturing the same according to the embodiments of the present invention, with reference to the drawings. It should be noted that identical components in the drawings are assigned the same numeral and, therefore, the explanation thereof may not be repeated. Also note that since the drawings mainly illustrate components in schematic form for the sake of clarity, the actual shape and the like of the components may be different from those shown in the drawings.

### First Embodiment

A semiconductor device in the first embodiment includes an optical element and a light transmitting element. The optical element has a surface including a portion that is convex in shape, and refracts light with this convex portion. The light transmitting element is bonded to the optical element so as to cover the convex portion of the optical element. The semiconductor device is characterized by that one of the optical element and the light transmitting element that is positioned higher than the other has a flat upper surface. To be more specific, in the present embodiment, the convex portion is convex upward, that is, in the direction from the bottom toward the top of the semiconductor device, and an upper surface of the light transmitting element (i.e., a surface opposite to the surface covering the convex portion of the optical element) that is the uppermost surface of the semiconductor device is flat.

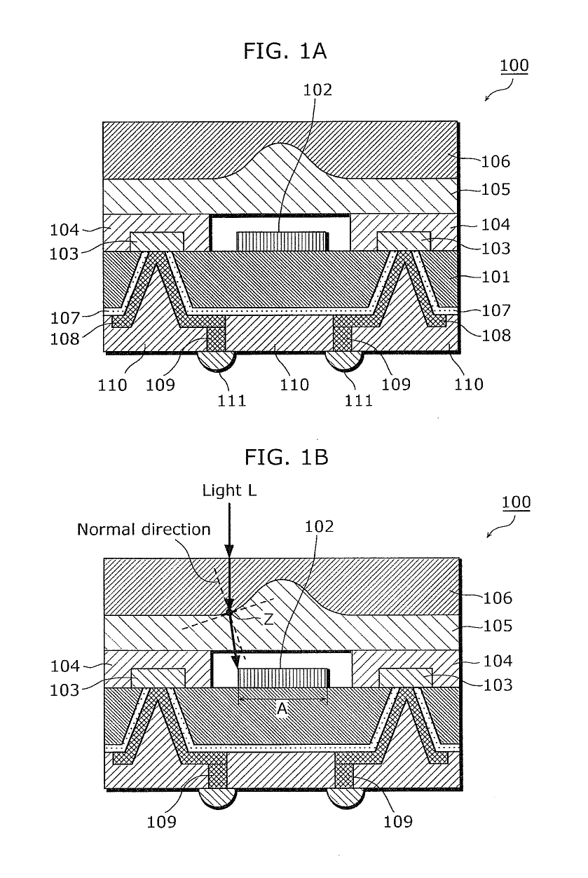

FIG. 1A is a detailed cross-sectional diagram showing a semiconductor device 100 in the first embodiment. As shown, the semiconductor device 100 includes a substrate 101, an imaging area 102, an electrode portion 103, a bonding element 104, an optical element 105, a light transmitting element 106, an insulating film 107, a conductive layer 108, an external electrode 109, an insulating layer 110, and a solder ball 111.

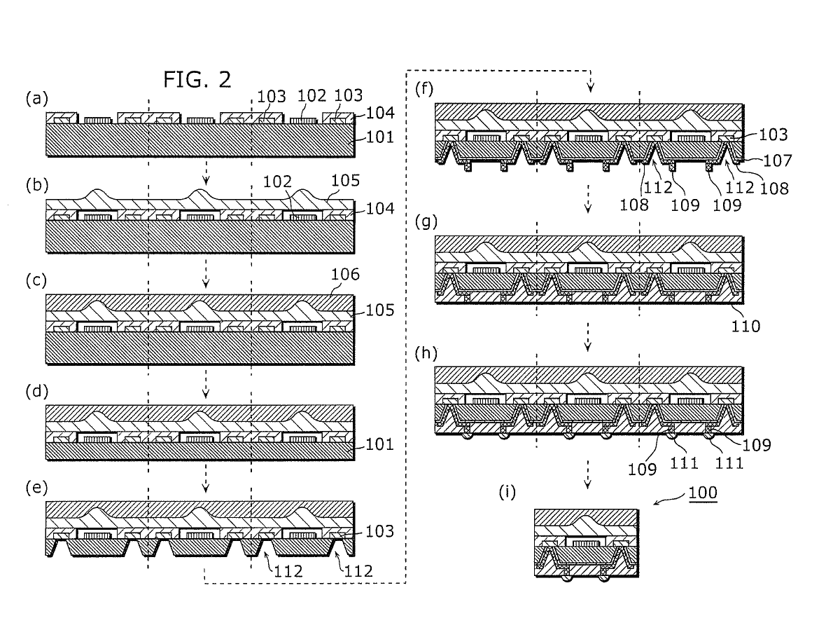

The substrate 101 is a part of a semiconductor wafer. In the substrate 101, a semiconductor element which includes a drive circuit for driving the imaging area 102 is formed. The semiconductor element has first and second main surfaces opposite to each other. The electrode portion 103 is formed on the first main surface which is the upper surface whereas the external electrode 109 is formed on the second main surface which is the lower surface. Also, in the substrate 101 (or, the semiconductor element), a through hole which is shown as the through hole 112 in FIG. 2 is formed. In the through hole 112, the conductive layer 108 that electrically connects the electrode portion 103 and the external electrode 109 is formed as shown in FIG. 1A. More specifically, the through hole 112 is formed so as to penetrate the substrate 101, that is, the semiconductor element.

Note that the semiconductor wafer is made of, for example, silicon (Si), germanium (Ga), or a compound semiconductive material such as gallium arsenide (GaAs), Indium phosphide (InP), gallium nitride (GaN), or silicon carbide (SiC). The semiconductor wafer is a disk-shaped semiconductor substrate which is about 50 to 800 μm in thickness and about 2 to 15 inches in diameter. It should be noted that because the lower surface of the semiconductor wafer is polished at the time of manufacture, the thickness of the substrate 101 is reduced to about 10 to 500 μm.

The imaging area 102 includes an imaging device formed on the upper surface of the substrate 101. The imaging device converts light incident from outside (referred to as the outside light hereafter) which has passed through the optical element 105 and the light transmitting element 106 into an electric signal. The electric signal obtained by this conversion is transmitted to the external electrode 109 via the electrode portion 103 and the conductive layer 108.

The electrode portion 103 is an example of a first electrode formed on the upper surface of the substrate 101 in such a manner to sandwich the imaging area 102 as shown in FIG. 1A. The conductive layer 108 is formed in the through hole 112, which is located immediately beneath the electrode portion 103 as viewed in FIG. 1A in the direction from the upper surface toward the lower surface of the substrate 101. The electrode portion 103 is electrically connected to the conductive layer 108, and transmits the electric signal obtained through the conversion performed in the imaging area 102 to the external electrode 109 via the conductive layer 108. The electrode portion 103 is about 1 μm in thickness, and is made of a metal such as titanium (Ti), copper (Cu), nickel (Ni), or gold (Au).

The bonding element 104 is placed on the upper surface of the substrate 101 so as to cover the electrode portion 103. The bonding element 104 is formed as follows. A coating of resin such as epoxy, silicone, or acrylic is applied to a corresponding region, and then the coating, which is the bonding element 104, is cured according to a predetermined method.

The optical element 105 is placed so as to be higher than the upper surface of the substrate 101, and is bonded to the substrate 101 via the bonding element 104. The optical element 105 has two parallel surfaces. Of these surfaces, a surface which is opposite to the upper surface of the substrate 101 and is bonded to the upper surface of the substrate 101 via the bonding element 104 is basically flat.

The other surface of the optical element 105 has the convex portion for refracting light. The position and shape of this convex portion is determined such that the outside light passing through the convex portion is collected on the imaging area 102. That is, the convex portion is formed at such a position and in such a shape that the light is directed toward the imaging area 102.

To be more specific, the convex portion is convex in the upward direction from the flat lower surface of the optical element 105, that is, the upward direction as viewed in FIG. 1A from the bottom toward the top of the semiconductor device 100. The convex portion is positioned above the imaging area 102, as shown in FIG. 1A. It should be noted that the optical element 105 is made of glass whose refractive index is about 1.50 to 1.64 or resin, for example. The thickness of the optical element is about 0.05 to 1.0 mm.

The light transmitting element 106 is bonded to the optical element 105 so as to cover the convex portion of the optical element 105. Of the surfaces of the light transmitting element 106, a surface opposite to the surface that is bonded to the optical element 105, that is, the upper surface serving as the outside-light incident surface, is flat. In short, the upper surface of the light transmitting element 106 is flat. It should be noted that, even when having an asperity smaller than at least the size of the convex portion of the optical element 105, the upper surface of the light transmitting element 106 is considered to be flat. In such a case, however, the aforementioned asperity is of a size that does not become a problem when a process of holding by suction is performed. The light transmitting element 106 is made of, for example, an acrylic resin whose refractive index is about 1.49. The refractive index of the light transmitting element 106 is higher than that of air and lower than that of the optical element 105.

The insulating film 107 is formed so as to cover the lower surface of the substrate 101 and an inner surface of the through hole 112 formed in the substrate 101. Note that the insulating film 107 is not formed over at least a part of an upper opening of the through hole 112 to which the electrode portion 103 is exposed, so that the electrode portion 103 and the conductive layer 108 are electrically connected. The insulating film 107 is a silicon dioxide film, for example.

The conductive layer 108 is an example of a conductive portion, which is formed on the inner surface of the through hole 112. The conductive layer 108 electrically connects the electrode portion 103 and the external electrode 109 so as to transmit, from the electrode portion 103 to the external electrode 109, the electric signal received from the imaging area 102. The conductive layer 108 is made of a metal such as Ti, Cu, Ni, or Au, and is about 0.1 to 2 μm in thickness.

The external electrode 109 is an example of a second electrode, which is formed so as to come into contact with the conductive layer 108. The external electrode 109 transmits the electric signal obtained through the conversion performed in the imaging area 102 to an external source via the solder ball 111. The external electrode 109 is made of a metal such as Ti, Cu, Ni, or Au.

The insulating layer 110 is formed on the entire lower surface of the substrate 101, except for a region where the external electrode 109 is formed. The insulating layer 110 is a silicon dioxide film, for example.

The solder ball 111 is a dome-shaped solder bump. By forming the solder ball 111 on the lower surface of the semiconductor device 100, mountability of the semiconductor device 100 onto an electronic substrate can be improved.

Note that the semiconductor device 100 shown in FIG. 1A has a function as an optical device. To be more specific, the semiconductor device 100 has a function of capturing outside light into an internal imaging element (namely, the imaging area 102) and electrically converting the captured image before providing the image to the side of the external electrode 109.

FIG. 1B is a cross-sectional diagram explaining an optical property of the semiconductor device 100 in the first embodiment.

The outside light (i.e., the captured image) passes through the light transmitting element 106, and is refracted toward the center of the semiconductor device 100 by the optical element 105 having the convex portion. As a result, the outside light is collected on the imaging area 102. FIG. 1B explains the light collection by schematically showing a light L incident, almost vertically, upon the outside-light incident surface of the light transmitting element 106, that is, upon the surface opposite to the surface that is bonded to the optical element 105.

The light L incident, almost vertically, upon the outside-light incident surface of the light transmitting element 106 passes through the light transmitting element 106, keeping an incident angle as it is because the outside-light incident surface of the light transmitting element 106 is basically flat. Then, at an interface surface between the light transmitting element 106 and the optical element 105 having the convex portion, i.e., at an inflection point Z in FIG. 1B, the light L is refracted toward the center of the semiconductor device 100 in the direction slightly deviating outward from the normal direction of the convex portion of the optical element 105. More specifically, the light L is refracted more toward the center of the semiconductor device 100 with respect to the incident angle. Accordingly, the light is collected on the imaging area 102.

Here, by the use of a material, for the light transmitting element 106, whose refractive index is higher than that of air and lower than that of the optical element 105, the light L can be refracted at the inflection point Z and then collected on the imaging area 102. As one example, an acrylic resin whose refractive index is about 1.49 is used for the light transmitting element 106, and glass whose refractive index is about 1.50 to 1.64 is used for the optical element 105. It should be noted that the refraction index may change depending on the quality of the material used or the wavelength of the light L.

In this way, the optical element 105 allows the light L to be collected on the imaging area 102. Thus, an area A of the imaging area 102 can be reduced in size, which results in miniaturization of the semiconductor device 100. Moreover, the light transmitting element 106 having the flat surface is bonded to the optical element 105 having the convex portion. To be more specific, the upper surface of the light transmitting element 106 which is positioned higher than the optical element 105 is flat. Therefore, it is easy to hold the semiconductor device 100 by suction when the semiconductor device 100 is to be mounted on an electronic substrate. Accordingly, the manufacturing cost can be reduced.

In the present embodiment, the light transmitting element 106 is bonded to the light element 105. However, a coating of the light transmitting element 106 may be applied onto the light element 105. Also, this light transmitting element 106 may be used as a light filter, and a material used for the light transmitting element 106 or the optical element 105 may be selected such that only the light of a desired wavelength is transmitted. In this case, the optical property of the semiconductor device 100 can be more improved.

Next, a method of manufacturing the semiconductor device 100 in the first embodiment is explained. FIG. 2 is a cross-sectional diagram showing each stage of the method of manufacturing the semiconductor device 100 in the present embodiment.

As shown in (a) of FIG. 2, the substrate 101, namely, the semiconductor wafer, is virtually divided into equal portions. On the virtually-divided substrate 101, a plurality of semiconductor elements are formed. Then, on each of the semiconductor elements, the imaging area 102 and the electrode portion 103 are formed at respective predetermined positions. Next, the bonding element 104 is applied to the electrode portion 103 formed on the semiconductor element.

As shown in (b) of FIG. 2, the optical element 105 made of glass or the like is fixed to the substrate 101 via the bonding element 104 so as to cover the imaging area 102 on the semiconductor element formed in the substrate 101 (the semiconductor wafer). Here, the optical element 105 has a plurality of convex portions. For this reason, the optical element 105 is held at its flat parts through vacuum suction, in general. Note that the optical element 105 is formed so that the convex portions become convex upward as shown in (b) of FIG. 2.

The optical element 105 is fixed to the substrate 101 in the following way. First, a coating of the bonding element 104 is applied to the substrate 101 (the semiconductor wafer). Examples as the method to apply this coating include an application method using a dispenser, a printing method, and a spin-coating method using a spinner. After this, the optical element 105 is placed on the substrate 101 and, at this time, pressure is applied to the optical element 105.

When the bonding element 104 is cured, the fixing of the optical element 105 is completed. In the case where the bonding element 104 is an ultraviolet curable material, the bonding element 104 is cured with ultraviolet irradiation passing through the optical element 105. On the other hand, in the case where the bonding element 104 is a thermosetting material, the bonding element 104 is headed to 50 to 200° C. by the use of a hardening furnace, an electrical hot plate, or an infrared lamp.

Moreover, as shown in (c) of FIG. 2, the light transmitting element 106 is fixed to the optical element 105. In the present example, the light transmitting element 106 is fixed to the optical element 105 which has been solely fixed to the substrate 101 in advance. However, the optical element 105 and the light transmitting element 106 may be bonded together in advance, so that two stages of processing can be reduced to one stage. In this case, since the light incident surface of the light transmitting element 106 is flat, the optical element 105 fixed to the light transmitting element 106 can also be easily held by suction. Furthermore, in the present embodiment, the optical element 105 which has been previously thinned is prepared. However, the optical element 105 having the convex portion may be firstly fixed to the light transmitting element 106, and then the flat surface of the optical element 105, that is, the surface opposite to the surface having the convex portion, may be thinned through, for example, polishing.

Next, as shown in (d) of FIG. 2, the lower surface of the substrate 101 (the semiconductor wafer) is polished, so that the thickness of the substrate 101 is reduced. After the polishing, the thickness of the substrate 101 is reduced to about 10 to 500 μm. Examples as the method to polish the substrate 101 include: a mechanical polishing method performed by applying pressure to the substrate 101 against a rotating grindstone; and a dry etching method. Here, because of the flat surface of the light transmitting element 106 bonded to the optical element 105 having the convex portion, pressure can be easily applied during the polishing.

Then, as shown in (e) of FIG. 2, the through hole 112 is formed immediately beneath the electrode portion 103 formed on the substrate 101 (the semiconductor wafer). More specifically, the through hole 112 is formed, penetrating the substrate 101 to reach the electrode portion 103. As one example of the method to form the through hole 112, a resist or the like is selectively formed over the lower surface of the substrate 101 and then an exposed part of the substrate 101 is etched through plasma etching or wet etching. At this time, Si and an insulating film present on the lower surface of the electrode portion 103 are also removed, so that the lower surface of the electrode portion 103 is exposed.

Next, as shown in (f) of FIG. 2, the insulating film 107, such as a silicon dioxide film, is formed on the inner surface of the through hole 112 and on the entire lower surface of the substrate 101 (the semiconductor wafer). After this, the insulating film 107 present over the upper opening of the through hole 112 is removed through, for example, photo-etching. The insulating film 107 can be easily formed according to, for example, a method of forming a silicon dioxide film through plasma chemical vapor deposition (plasma CVD) or a method of forming a polyimide resin or the like through spin-coating.

After this, the conductive layer 108 and the external electrode 109 are selectively formed on the inner surface of the through hole 112 and on the lower surface of the substrate 101. Here, the insulating film 107 is temporarily formed over the upper opening of the through hole 112 (i.e., the exposed lower surface of the electrode portion 103). Thus, after a photoresist is selectively formed according to a photolithography method, the insulating film 107 present over the upper opening of the through hole 112 is removed through plasma etching or wet etching.

The conductive layer 108 is formed on the inner surface of the through hole 112 as follows. A Ti/Cu film is evaporated onto the inner surface of the through hole 112 according to a sputtering method or the like, and then a metal film made of, for example, Ni, Cu, or Au is formed according to an electrolytic plating method. Here, the thickness of the metal film is about 0.1 to 2 μm. Before the sputtering deposition of the metal film, the electrode portion 103 exposed to the upper opening of the conducive through hole 112 is slightly etched through dry etching or wet etching. As a result, the electrode portion 103 and the evaporated metal film are connected with a low resistance. Here, since the thickness of the electrode portion 103 is only 1 μm or so, the etching process is controlled so as not to over-etch the electrode portion 103 positioned at the upper opening of the through hole 112.

Accordingly, the conductive layer 108 is formed through the plating process. The plating process is performed according to an electrolytic or nonelectrolytic plating method, for example. In (f) of FIG. 2, the conductive layer 108 is formed only on the inner surface of the through hole 112. However, the conductive layer 108 may fill in the through hole 112. The external electrode 109 is formed through the plating process as well.

Next, as shown in (g) of FIG. 2, the insulating layer 110 is formed. As is the case with the insulating film 107, the insulating layer 110 is formed according to, for example, the method of forming a silicon dioxide film through the plasma CVD or the method of forming a polyimide resin or the like through the spin-coating.

Then, as shown in (h) of FIG. 2, the solder ball 111 is formed in a region where the external electrode 109 is formed, which improves mountability of the semiconductor device 100 onto an electronic substrate. In the present embodiment, the insulating layer 110 is formed after the conductive layer 108 and the external electrode 109 are set as described above. However, the insulating layer 110 may be formed after the solder ball 111 is formed.

Finally, as shown in (i) of FIG. 2, the substrate 101 (the semiconductor wafer) is separated into the individual semiconductor pieces along cutoff lines indicated by broken lines in FIG. 2. As a consequence, the semiconductor device 100 is completed. The separation into the individual semiconductor devices 100, that is, the singulation of the substrate 101, is performed according to a dicing method. To be more specific, the optical element 105, the light transmitting element 106, and so forth are cut simultaneously with the substrate 101.

When the solder ball 111 shown in (h) of FIG. 2 is to be formed on the substrate 101 or when the singulation of the substrate 101 is to be performed, vacuum suction can be achieved because the light transmitting element 106 is made of a transmissive material having the flat surface, that is, because the upper surface of the light transmitting element 106 is flat. On account of this flat upper surface, it becomes easy to singulate the substrate 101 having the solder balls 111. Thus, as compared to the conventional manufacturing method whereby the solder balls are formed on the substrate after the substrate is singulated into individual pieces, the productivity can be dramatically increased and the manufacturing cost can be accordingly reduced.

The completed semiconductor device 100 as shown in FIG. 1A is a device which is reduced in size and thickness, which ensures a dramatically high degree of productivity, and which has an excellent optical property.

As described thus far, the semiconductor device 100 in the present embodiment includes the optical element 105 having the convex portion with which the outside light can be efficiently collected on the imaging area 102. Thus, the size of the semiconductor device 100 itself can be reduced. Also, the light transmitting element 106 having the flat surface is fixed to the optical element 105 having the convex portion. This can make it easy to hold the semiconductor device 100 by suction when the semiconductor device 100 is to be mounted on an electronic substrate, thereby reducing the manufacturing cost. Moreover, when the processing such as polishing is performed on the lower surface of the semiconductor device 100 on which the external electrode 109 is formed, the semiconductor device 100 can be held by suction at the flat surface of the light transmitting element 106. Thus, the semiconductor device 100 can be easily thinned.

### Second Embodiment

As in the case of the first embodiment, a semiconductor device in the second embodiment includes an optical element and a light transmitting element. The optical element has a surface including a portion that is convex in shape, and refracts light with this convex portion. The light transmitting element is bonded to the optical element so as to cover the convex portion of the optical element. The semiconductor device is characterized by that one of the optical element and the light transmitting element that is positioned higher than the other has a flat upper surface. To be more specific, in the present embodiment, the convex portion is convex downward, that is, in the direction from the top toward the bottom of the semiconductor device, and an upper surface of the optical element (i.e., a surface opposite to the surface having the convex portion) that is the uppermost surface of the semiconductor device is flat.

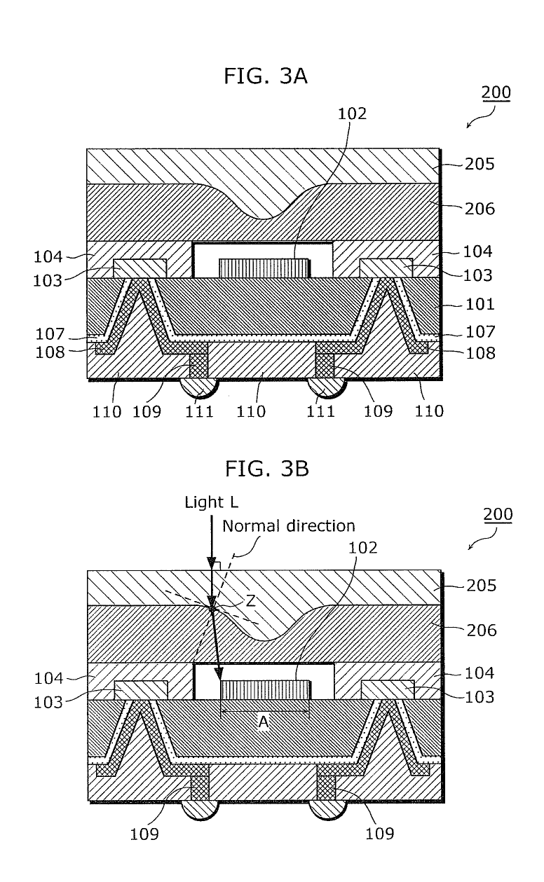

FIG. 3A is a detailed cross-sectional diagram showing a semiconductor device 200 in the second embodiment. The semiconductor device 200 shown in FIG. 3A is different from the semiconductor device 100 in the first embodiment in that an optical element 205 and a light transmitting element 206 are provided in place of the optical element 105 and the light transmitting element 106, respectively. In the following, description of points identical to those in the first embodiment is omitted, and the points of difference are mainly described.

As shown in FIG. 3A, in the case of the semiconductor device 200 in the present embodiment, the light transmitting element 206 is placed on the upper surface of the substrate 101 and the optical element 205 is placed on the light transmitting element 206.

The optical element 205 is placed on the light transmitting element 206. The optical element 205 has: a convex surface including a convex portion which is convex downward; and a flat surface which is opposite to the convex surface. It should be noted that, even when the flat surface has an asperity smaller than at least the size of the convex portion, the present surface is considered to be flat. In such as case, however, the aforementioned asperity is of a size that does not become a problem when the process of holding by suction is performed. The optical element 205 is made of glass or resin, for example. The thickness of the optical element 205 is about 0.05 to 1.0 mm.

The position and shape of the convex portion is determined such that the outside light passing through the convex portion is collected on the imaging area 102. For example, the convex portion is convex in the downward direction from the upper surface to the lower surface of the optical element 205, that is, in the downward direction as viewed in FIG. 3A from the top toward the bottom of the semiconductor device 200. The convex portion is positioned above the imaging area 102.

The light transmitting element 206 is bonded to the optical element 205 so as to cover the convex portion of the optical element 205. Of the surfaces of the light transmitting element 206, the surface opposite to the surface that is bonded to the optical element 205 is flat and is bonded to the upper surface of the substrate 101 via the bonding element 104.

As is the case with the semiconductor device 100 shown in FIG. 1A, the semiconductor device 200 shown in FIG. 3A has a function as an optical device. To be more specific, the semiconductor device 200 has a function of capturing outside light into an internal imaging element (namely, the imaging area 102) and electrically converting the captured image before providing the image to the side of the external electrode 109.

An optical property of the semiconductor device 200 in the second embodiment is explained with reference to FIG. 3B. FIG. 3B is a cross-sectional diagram explaining the optical property of the semiconductor device 200.

Here, the outside light is refracted toward the center of the semiconductor device 200 by the optical element 205 having the convex portion, and passes through the light transmitting element 206. As a result, the outside light is collected on the imaging area 102. FIG. 3B explains the light collection by schematically showing a light L incident, almost vertically, upon the outside-light incident surface of the optical element 205, that is, upon the surface opposite to the surface having the convex portion.

The light L incident, almost vertically, upon the outside-light incident surface of the optical element 205 passes through the optical element 205, keeping an incident angle as it is because the outside-light incident surface of the optical element 205 is basically flat. Then, at an interface surface between the convex surface of the optical element 205 and the light transmitting element 206, i.e., at an inflection point Z in FIG. 3B, the light L is refracted toward the center of the semiconductor device 100 instead of the normal direction of the convex portion of the optical element 205. Accordingly, the light is collected on the imaging area 102.

Here, by the use of a material, for the light transmitting element 206, whose refractive index is higher than that of air and lower than that of the optical element 205, the light L can be refracted at the inflection point Z and then collected on the imaging area 102. As one example, an acrylic resin whose refractive index is about 1.49 is used for the light transmitting element 206, and glass whose refractive index is about 1.50 to 1.64 is used for the optical element 205. It should be noted that the refraction index may change depending on the quality of the material used or the wavelength of the light L.

Here, the refractive index of the light transmitting element 206 is higher than that of air. On this account, the light L refracted toward the center of the semiconductor device 200 at the inflection point Z is further refracted toward the center of the semiconductor device 200 at an interface surface between the light transmitting element 206 and air. Thus, more light can be collected on the imaging area 102. Also, an area of the imaging area 102 can be reduced in size.

In this way, the optical element 205 allows the light L to be collected on the imaging area 102. Thus, an area A of the imaging area 102 can be reduced in size, which results in miniaturization of the semiconductor device 200. Moreover, the upper surface of the optical element 205, that is, the surface opposite to the surface having the convex portion, is flat. Therefore, it is easy to hold the semiconductor device 200 by suction when the semiconductor device 200 is to be mounted on an electronic substrate. This can reduce the manufacturing cost. Furthermore, both the light transmitting element 206 and the bonding element 104 are made of organic materials, meaning that bonding between the light transmitting element 206 and the bonding element 104 is strong.

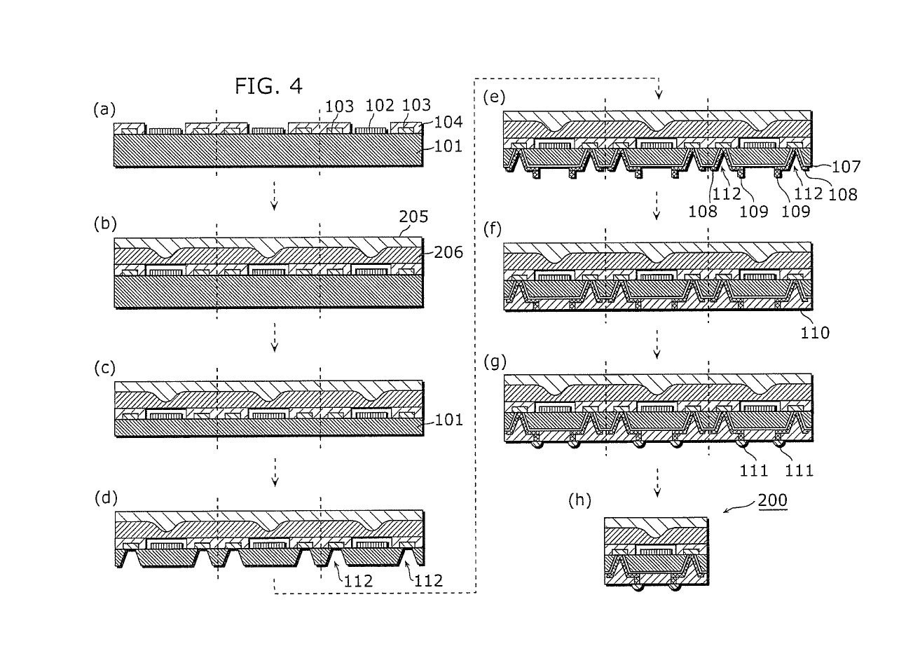

Next, a method of manufacturing the semiconductor device 200 in the second embodiment is explained. FIG. 4 is a cross-sectional diagram showing each stage of the method of manufacturing the semiconductor device 200 in the present embodiment. In the following description, the explanations of stages identical to those in the first embodiment are not repeated, and different stages are thus mainly explained.

As shown in (a) of FIG. 4, the substrate 101, namely, the semiconductor wafer, is virtually divided into equal portions. On the virtually-divided substrate 101, a plurality of semiconductor elements are formed. Then, on each of the semiconductor elements, the imaging area 102 and the electrode portion 103 are formed at respective predetermined positions. Next, the bonding element 104 is applied to the electrode portion 103 formed on the semiconductor element.

Next, as shown in (b) of FIG. 4, the optical element 205 on which the light transmitting element 206 has been attached in advance is fixed to the substrate 101 using the bonding element 104, so as to cover the imaging area 102. Here, the optical element 205 is formed so that the convex portion included in the convex surface of the optical element 205 is convex downward as shown in (b) of FIG. 4.

Here, the optical element 205 on which the light transmitting element 206 has been attached in advance is fixed to the substrate 101 in the following way. First, a coating of the bonding element 104 is applied to the substrate 101 (the semiconductor wafer). Examples as the method to apply the coating include an application method using a dispenser, a printing method, and a spin-coating method using a spinner. After this, the optical element 205 is placed on the substrate 101 so that the light transmitting element 206 and the bonding element 104 are bonded together and, at this time, pressure is applied to the optical element 205.

When the bonding element 104 is cured, the fixing of the optical element 205 on which the light transmitting element 206 has been attached in advance is completed. In the case where the bonding element 104 is an ultraviolet curable material, the bonding element 104 is cured with ultraviolet irradiation passing through the optical element 205 and the light transmitting element 206. On the other hand, in the case where the bonding element 104 is a thermosetting material, the bonding element 104 is headed to 50 to 200° C. by the use of a hardening furnace, an electrical hot plate, or an infrared lamp.

It should be noted that the method of attaching the light transmitting element 206 to the optical element 205 so as to cover the convex portion of the optical element 205 is the same method as described with reference to (c) of FIG. 2 in the first embodiment.

The subsequent processes from the polishing process performed on the lower surface of the substrate 101 are the same as those in the first embodiment and, therefore, the explanations thereof are not repeated in the present embodiment. More specifically, the processes performed in stages shown in (c) to (h) of FIG. 4 corresponds to the processes performed in the stages shown in (d) to (i) of FIG. 2, respectively.

As described thus far, the semiconductor device 200 in the present embodiment includes the optical element 205 having the convex portion with which the outside light can be efficiently collected on the imaging area 102. Thus, the size of the semiconductor device 200 itself can be reduced. Also, the optical element 205 has the flat surface opposite to the convex surface. This can make it easy to hold the semiconductor device 200 by suction when the semiconductor device 200 is to be mounted on an electronic substrate, thereby reducing the manufacturing cost. Moreover, when the processing such as polishing is performed on the lower surface of the semiconductor device 200 on which the external electrode 109 is formed, the flat surface of the optical element 205 can be held by suction. Thus, the semiconductor device 200 can be easily thinned. Furthermore, both the light transmitting element 206 and the bonding element 104 are made of organic materials, meaning that bonding between the light transmitting element 206 and the bonding element 104 is strong.

### Third Embodiment

A semiconductor device in the third embodiment includes an optical element which has: a convex surface including a convex portion that is convex downward (in the direction from the top toward the bottom of the semiconductor device); and a flat surface that is opposite to the convex surface.

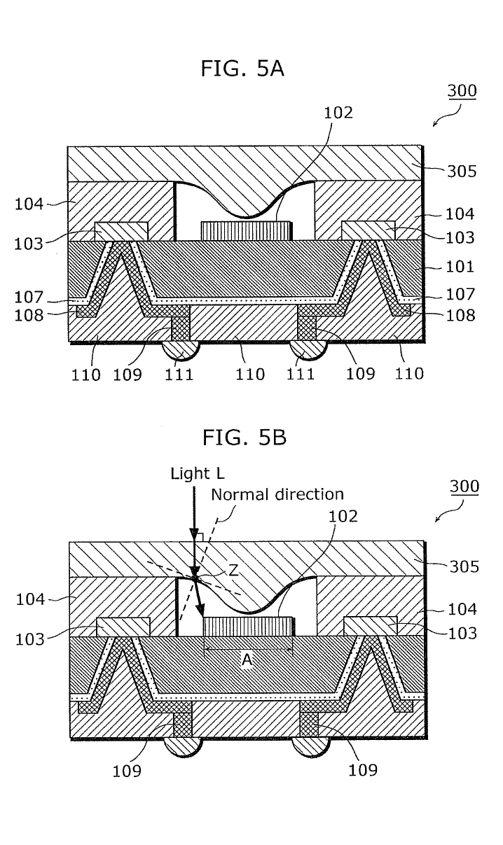

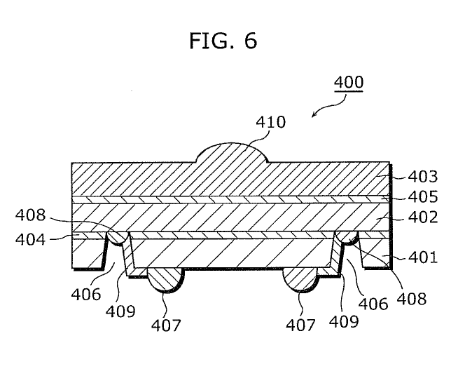

FIG. 5A is a detailed cross-sectional diagram showing a semiconductor device 300 in the third embodiment. The semiconductor device 300 shown in FIG. 5A is different from the semiconductor device 200 in the second embodiment in that an optical element 305 is provided in place of the optical element 205 and that the light transmitting element 206 is not provided. In the following, description of points identical to those in the second embodiment is omitted, and the points of difference are mainly described.

As shown in FIG. 5A, in the case of the semiconductor device 300 in the third embodiment, the optical element 305 is formed above the upper surface of the substrate 101. Unlike the cases described in the first and second embodiments, the semiconductor device 300 in the present embodiment does not include a light transmitting element.

The optical element 305 has: a convex surface including a convex portion which is convex downward; and a flat surface which is opposite to the convex surface. It should be noted that, even when the flat surface has an asperity smaller than at least the size of the convex portion, the present surface is considered to be flat. In such as case, however, the aforementioned asperity is of a size that does not become a problem when the process of holding by suction is performed. The optical element 305 is made of glass or resin, for example. The thickness of the optical element 205 is about 0.05 to 1.0 mm.

The position and shape of the convex portion is determined such that the outside light passing through the convex portion is collected on the imaging area 102. For example, the convex portion is convex in the downward direction from the upper surface to the lower surface of the optical element 305, that is, in the downward direction as viewed in FIG. 5A from the top toward the bottom of the semiconductor device 300. The convex portion is positioned above the imaging area 102.

As is the case with the semiconductor device 200 shown in FIG. 3A, the semiconductor device 300 shown in FIG. 5A has a function as an optical device. To be more specific, the semiconductor device 300 has a function of capturing outside light into an internal imaging element (namely, the imaging area 102) and electrically converting the captured image before providing the image to the side of the external electrode 109.

An optical property of the semiconductor device 300 in the third embodiment is explained with reference to FIG. 5B. FIG. 5B is a cross-sectional diagram explaining the optical property of the semiconductor device 300.

Here, the outside light is refracted toward the center of the semiconductor device 300 by the optical element 305 having the convex portion. As a result, the outside light is collected on the imaging area 102. FIG. 5B explains the light collection by schematically showing a light L incident, almost vertically, upon the outside-light incident surface of the optical element 305, that is, upon the surface that does not have the convex portion.

The light L incident, almost vertically, upon the outside-light incident surface of the optical element 305 passes through the optical element 305, keeping an incident angle as it is because the outside-light incident surface of the optical element 305 is basically flat. Then, at an interface surface between the convex surface of the optical element 305 and air, i.e., at an inflection point Z in FIG. 5B, the light L is refracted toward the center of the semiconductor device 300 instead of the normal direction of the convex portion of the optical element 305. Accordingly, the light is collected on the imaging area 102.

Here, the refractive index of the optical element 305 is higher than that of air. On this account, the light L can be collected on the imaging area 102 at the inflection point Z.

In this way, the optical element 305 allows the light L to be collected on the imaging area 102. Thus, an area A of the imaging area 102 can be reduced in size, which results in miniaturization of the semiconductor device 300. Moreover, the upper surface of the optical element 305, that is, the surface opposite to the surface having the convex portion, is flat. Therefore, it is easy to hold the semiconductor device 300 by suction when the semiconductor device 300 is to be mounted on an electronic substrate. This can reduce the manufacturing cost. Furthermore, since a light transmitting element is not included in the present embodiment, it is possible that the semiconductor device 300 may decrease in strength. However, the thickness of the semiconductor device 300 can be reduced.

Here, a method of manufacturing the semiconductor device 300 in the present embodiment is almost the same as the method of manufacturing the semiconductor device 200 explained in the second embodiment. To be more specific, the method of the present embodiment is different from that of the second embodiment only in the following point. In the stage shown in (b) of FIG. 4 in the second embodiment, the optical element 205 on which the light transmitting element 206 has been attached in advance is fixed to the substrate 101. On the other hand, in the present embodiment, only the optical element 305 is fixed to the substrate 101. Also, it should be noted that, when the semiconductor device 300 in the present embodiment is manufactured, the thickness of the bonding element 104 needs to be increased in order for the downward-convex portion of the optical element 305 not to come into contact with the imaging area 102.

As described thus far, the semiconductor device 300 in the present embodiment includes the optical element 305 having the convex portion with which the outside light can be efficiently collected on the imaging area 102. Thus, the size of the semiconductor device 300 itself can be reduced. Also, the optical element 305 has the flat surface opposite to the convex surface. This can make it easy to hold the semiconductor device 300 by suction when the semiconductor device 300 is to be mounted on an electronic substrate, thereby reducing the manufacturing cost. Moreover, when the processing such as polishing is performed on the lower surface of the semiconductor device 300 on which the external electrode 109 is formed, the flat surface of the optical element 305 can be held by suction. Thus, the semiconductor device 300 can be easily thinned. Furthermore, since a light transmitting element is not included in the present embodiment, it is possible that the semiconductor device 300 may decrease in strength. However, the thickness of the semiconductor device 300 can be more reduced.

The semiconductor device and the method of manufacturing the same according to the present invention have been explained thus far on the basis of the above embodiments. However, the present invention is not limited to these embodiments. The present invention includes other embodiments implemented by applying modifications conceived by those skilled in the art or by combining components of the different embodiments as long as these other embodiments do not depart from the scope of the present invention.

For example, a light receiving element such as a photo integrated circuit (IC) may be formed instead of the imaging area 102 formed on the substrate 101 in the above embodiments.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The semiconductor device and the method of manufacturing the same according to the present invention have advantageous effects of reducing the time taken in the manufacturing process and of improving manufacturing yield. Thus, the present invention is useful as a digital camera, a cellular phone, and the like which are required to be of higher performance, to be thinner, and to be smaller in the future.

What is claimed is:

1. A semiconductor device comprising:
a semiconductor element which includes an imaging area for converting light into an electric signal, and has a first main surface and a second main surface that is opposite to said first main surface;
a first electrode formed on said first main surface;
a second electrode formed on said second main surface;
a conductive portion which is formed in a through hole penetrating said semiconductor element, and is configured to electrically connect said first and second electrodes so as to transmit, from said first electrode to said second electrode, the electric signal received from said imaging area;
an optical element which is bonded to said first main surface via a bonding element so as to be positioned higher than said first main surface, has a convex surface including a convex portion, and is configured to refract the light using the convex portion; and
a light transmitting element which is bonded to said optical element so as to cover the convex portion,
wherein one of said optical element and said light transmitting element that is positioned higher than the other has a flat upper surface.

2. The semiconductor device according to claim 1,
wherein said convex portion is convex upward, and
said light transmitting element is positioned higher than said optical element and has a flat surface opposite to a surface to which said optical element is bonded.

3. The semiconductor device according to claim 1,
wherein said convex portion is convex downward, and
said optical element is positioned higher than said light transmitting element and has a flat surface opposite to the convex surface.

4. The semiconductor device according to claim 1,
wherein a refractive index of said light transmitting element is higher than a refractive index of air and lower than a refractive index of said optical element.

5. The semiconductor device according to claim 1,
wherein said convex portion is formed in such a shape and at such a position that the light is directed toward said imaging area.

6. The semiconductor device according to claim 1,
wherein said light transmitting element is made of an acrylic resin, and
said optical element is made of glass.

7. A semiconductor device comprising:
a semiconductor element which includes an imaging area for converting light into an electric signal, and has a first main surface and a second main surface that is opposite to said first main surface;
a first electrode formed on said first main surface;
a second electrode formed on said second main surface;
a conductive portion which is formed in a through hole penetrating said semiconductor element, and is configured to electrically connect said first and second electrodes so as to transmit, from said first electrode to said second electrode, the electric signal received from said imaging area; and
an optical element which is positioned higher than said first main surface, and has: a convex surface including a convex portion that is convex downward; and a flat surface opposite to the convex surface.

8. A semiconductor-device manufacturing method comprising:
forming a semiconductor element which includes an imaging area for converting light into an electric signal and has a first main surface and a second main surface that is opposite to the first main surface;
forming a first electrode on the first main surface;
forming a through hole which penetrates the semiconductor element and forming, in the through hole, a conductive portion which is electrically connected to the first electrode;
placing an optical element so as to be higher than the first main surface, the optical element having a convex surface including a convex portion;
bonding a light transmitting element to the optical element so as to cover the convex portion; and
forming, on the second main surface, a second electrode which is electrically connected to the conductive portion,
wherein one of the optical element and the light transmitting element that is positioned higher than the other has a flat upper surface.

9. The semiconductor-device manufacturing method according to claim 8,
wherein, in said placing of an optical element, the optical element is placed so that the convex portion is convex upward, and
in said bonding, the light transmitting element having the flat upper surface is bonded to the optical element.

10. The semiconductor-device manufacturing method according to claim 8,
wherein, in said placing of an optical element, the optical element is placed so that the convex portion is convex downward, the optical element having a flat surface opposite to the convex surface.

11. The semiconductor-device manufacturing method according to claim 8, further comprising
polishing a surface opposite to the first main surface of the semiconductor element so as to form the second main surface,
wherein, in said forming of a second electrode, the second electrode is formed on the second main surface obtained as a result of said polishing.

12. A semiconductor-device manufacturing method comprising:
forming a semiconductor element which includes an imaging area for converting light into an electric signal and has a first main surface and a second main surface that is opposite to the first main surface;
forming a first electrode on the first main surface;
forming a through hole which penetrates the semiconductor element and forming, in the through hole, a conductive portion which is electrically connected to the first electrode;
placing an optical element so as to be higher than the first main surface, the optical element having: a convex surface including a convex portion that is convex downward; and a flat surface opposite to the convex surface; and
forming, on the second main surface, a second electrode which is electrically connected to the conductive portion.
